(19) United States
(12) Patent Application Publication
(10) Pub. No.: US 2008/0145697 A1
(43) Pub. Date: Jun. 19, 2008

(54) OPTO-ELECTRONIC DEVICES CONTAINING SULFONATED LIGHT-EMITTING COPOLYMERS

(75) Inventors: Jie Liu, Niskayuna, NY (US); Qing Ye, Schenectady, NY (US); Joyce Hung, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 11/610,061

(22) Filed: Dec. 13, 2006

(51) Int. Cl. B32B 27/00

(52) U.S. Cl. 428/690

(57) ABSTRACT

The invention provides opto-electronic devices comprising at least one sulfonated light emitting polymer. The at least one sulfonated light-emitting polymer is selected from sulfonated carbazoles, sulfonated fluorenes, sulfonated polyphenylene, sulfonated polyphenylene vinylenes and combinations thereof.

### BACKGROUND

The invention relates generally to opto-electronic devices comprising at least one sulfonated light-emitting polymer. The invention further relates to opto-electronic devices that comprise at least one sulfonated carbazoles, sulfonated fluorenes, sulfonated polyphenylenes, sulfonated polyphenylene vinylenes, and combinations thereof.

Organic light emitting devices (OLEDs), which make use of thin film materials that emit light when subjected to a voltage bias, are expected to become an increasingly popular form of flat panel display technology. This is because OLEDs have a wide variety of potential applications, including cellphones, personal digital assistants (PDAs), computer displays, informational displays in vehicles, television monitors, as well as light sources for general illumination. Due to their bright colors, wide viewing angle, compatibility with full motion video, broad temperature ranges, thin and conformable form factor, low power requirements and the potential for low cost manufacturing processes, OLEDs are seen as a future replacement technology for cathode ray tubes (CRTs) and liquid crystal displays (LCDs). Due to their high luminous efficiencies, OLEDs are seen as having the potential to replace incandescent, and perhaps even fluorescent, lamps for certain types of applications.

One approach to achieve full-color OLEDs includes energy transfer from host to emissive guest molecules. For this to be realized, the triplet energy state of the host has to be higher than the guest molecule. Carbazole derivatives have shown promise to perform well as host molecule in the presence of metal containing emissive guest molecules. Often used in this respect is poly(N-vinyl carbazole). However, quantum efficiencies of devices that use poly(N-vinyl carbazole) is still at the range of about 60 to 80%. Thus, there is a need in the art to develop OLEDs having device quantum efficiencies, while still maintaining the potential for the molecules to host red, green, and blue emissive complexes.

### BRIEF DESCRIPTION

In one aspect, the invention provides an opto-electronic device comprising at least one sulfonated light-emitting polymer. The at least one sulfonated light emitting polymer is selected from sulfonated carbazoles, sulfonated fluorenes, sulfonated polyphenylene, sulfonated polyphenylene vinylenes and combinations thereof. The opto-electronic device may additionally comprise at least one light-emitting polymer that is not sulfonated.

### DRAWINGS

These and other features, aspects, and advantages of the present invention will become better understood when the following detailed description is read with reference to the accompanying drawings in which like characters represent like parts throughout the drawings, wherein:

FIG. 1 shows brightness versus bias voltage curves for the device of Comparative Example 1 (diamonds) and the device of Example 9 (triangles).

FIG. 2 shows the efficiency versus current density curves for the device of Comparative Example 1 (diamonds) and the device of Example 9 (triangles)

FIG. 3 shows the current-voltage curves of the device of Comparative Example 1 (diamonds) and the device of Example 9 (triangles) measured under illumination.

### DETAILED DESCRIPTION

In one aspect, the invention provides an opto-electronic devices comprising at least one sulfonated light-emitting polymer. Sulfonated light-emitting polymer, as used herein, refers to a polymer wherein at least a few or all of the repeat units comprise a SO₃M group, wherein M is H, a metal cation, a non-metallic inorganic cation, an organic cation or a mixture thereof. The sulfonated light-emitting polymer may include, but is not limited to, sulfonated carbazoles, sulfonated fluorenes, sulfonated polyphenylene, sulfonated polyphenylene vinylenes, and the like, and combinations thereof. In many embodiments, particularly where the polymer is used in a hole injection layer or hole collection layer of an opto-electronic device, it may be desirable to utilize the acid form of the sulfonate groups in the polymer, in order to provide mobile protons. In this case, M is H or a mixture of H and one or more of the cations listed above, and in some embodiments, M is H.

Thus, in one aspect, the sulfonated light-emitting polymer comprises structural units of formula I

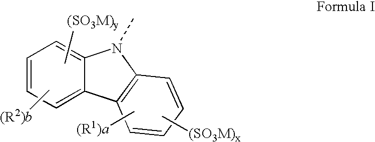

wherein R¹ and R² are independently at each occurrence a C₁-C₄₀ aliphatic radical, a C₃-C₂₀ aromatic radical, a C₃-C₂₀ cycloaliphatic radical;

### M is H, a metal cation, a non-metallic inorganic cation, an organic cation or a mixture thereof;

a and b are 0 or integers ranging from 1 to 4;
x is an integer ranging from 1 to 4, y is an integer ranging from 1 to 4, wherein x+a+b+y is less than 8.

Sulfonated carbazoles represented by formula I include polymers having pendant carbazole groups, and may comprise a wide range of family of polymers, such as polyethers, polyesters, polycarbonates, polyvinyls, and the like. Polyethers, polyesters, and polycarbonates containing carbazole groups are described in US Patent Applications filed under attorney docket numbers 205501 and 207853, the entire contents of which are incorporated herein by reference. In one particular embodiment, the sulfonated carbazoles is a sulfonated poly(vinyl carbazole) having formula

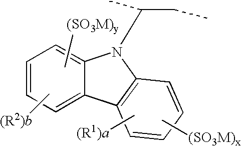

wherein R¹, R², M, a, b, x and y are as described in formula I. The poly(vinyl carbazole) may be synthesized in a facile manner by the addition polymerization of the corresponding monomer N-vinyl carbazole. Poly(N-vinyl carbazole) is commercially available.

Sulfonated light-emitting polymer having structural units of formula I may be obtained by the sulfonation of the corresponding polymer. Sulfonation may be achieved by using a suitable sulfonating agent known in the art. Such sulfonating agents include, but not limited to sulfuric acid, chlorosulfonic acid, acetyl sulfate, and the like. Methods of sulfonation are also known in the art. It may involve the use of a solvent and may be conducted at temperatures ranging from about −10° C. to about 50° C. The sulfonated polymer may then be isolated by techniques known in the art.

In another embodiment, the sulfonated light emitting polymer comprises structural units of formula II

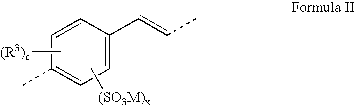

wherein R³ is a C₁-C₄₀ aliphatic radical, a C₃-C₂₀ aromatic radical, a C₃-C₂₀ cycloaliphatic radical;

### M is H, a metal cation, a non-metallic inorganic cation, an organic cation or a mixture thereof;

c is 0 or an integer ranging from 1 to 4;
x is an integer ranging from 1 to 4, wherein x+c is less than 4.

Polymers represented by structural units of formula II may be referred to as sulfonated polyphenylene vinylenes, and may be synthesized by the sulfonation of the corresponding parent polyphenylene vinylene. Polyphenylene vinylenes are also commercially available.

In yet another embodiment, the sulfonated light-emitting polymer comprises structural units of formula IIIa, or formula IIIb, or formula IIIc or formula IIId

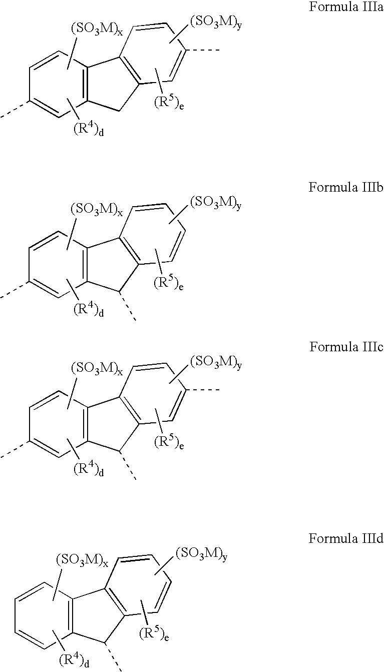

wherein R⁴ and R⁵ are independently at each occurrence a C₁-C₄₀ aliphatic radical, a C₃-C₂₀ aromatic radical, a C₃-C₂₀ cycloaliphatic radical;

### M is H, a metal cation, a non-metallic inorganic cation, an organic cation or a mixture thereof;

d and e are 0 or integers ranging from 1 to 4;
x is an integer ranging from 1 to 4, wherein x+d+e+y is less than 7.

Polymers having structural units of formula III may also be referred to in the art as sulfonated polyfluorenes. The parent polyfluorene may be obtained by standard carbon-carbon coupling reactions known in the art, such as Suzuki reaction, or Stille reaction, and the like. See for example, Burnell et al., Macromolecules, Vol. 38, pp. 10667-10677 (2005). Subsequently, the parent polymer may be sulfonated by methods already described.

In a further embodiment, the sulfonated fluorenes may comprise of polymers having structural units IIId

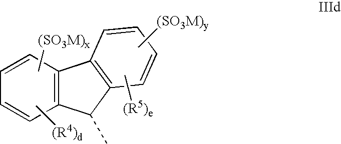

wherein R4, R5, M, d, and e are as defined before. Sulfonated fluorenes represented by formula IIId include polymers having pendant fluorene groups, and may comprise a wide range of family of polymers, such as polyethers, polyesters, polycarbonates, polyvinyls, and the like.

In yet another further embodiment, the sulfonated light-emitting polymer comprises structural units of formula IV

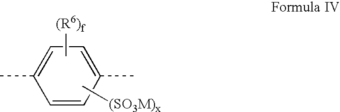

wherein R⁶ is a C₁-C₄₀ aliphatic radical, a C₃-C₂₀ aromatic radical, a C₃-C₂₀ cycloaliphatic radical;

### M is H, a metal cation, a non-metallic inorganic cation, an organic cation or a mixture thereof;

f is 0 or an integer ranging from 1 to 4;
x is an integer ranging from 1 to 4, wherein x+f is less than 4.

Polymers having structural units of formula IV may also be referred to in the art as sulfonated polyphenylenes. This may be obtained by the sulfonation of parent polyphenylene. Polyphenylenes may be synthesized by methods already known in the art. See for example, Fujimoto et al., Macromolecules Volume 38, pp. 5010-5016 (2005).

In some embodiments, the sulfonated light-emitting polymers comprises structural units of formula I. The sulfonated light-emitting polymer may further comprise structural units that are also unsulfonated, having formula V

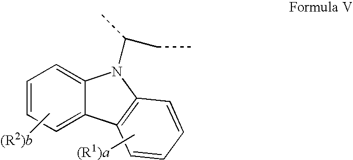

wherein R¹ and R² are independently at each occurrence a C₁-C₄₀ aliphatic radical, a C₃-C₂₀ aromatic radical, a C₃-C₂₀ cycloaliphatic radical;
a and b are 0 or integers ranging from 1 to 4.

The amount of sulfonation on the sulfonated light emitting polymer may range from about 5 mole % to about 95 mole % in one embodiment, from about 10 mole % to about 80 mole % in another embodiment, and from about 20 mole % to about 70 mole % in yet another embodiment. The term “mol % sulfonation” means mol % of the structural units derived from a sulfonated monomer and containing at least one sulfonate group, with respect to the total moles of structural units derived from the same monomer, but without sulfonate groups, and particularly refers to mol % of disulfonated structural units. Mole % may be determined by various techniques known in the art, and may include, but not limited to, NMR, titration, and x-ray photoelectron spectroscopy (XPS). In some specific embodiments, the sulfonated light emitting polymer comprises from about 5 mole % to about 95 mole % of structural units of formula I in one embodiment, from about 10 mole % to about 80 mole % of structural units of formula I in another embodiment, and from about 20 mole % to about 70 mole % of structural units of formula I in yet another embodiment.

Polymers comprising structural units of formula I that comprise pendant cabazole units show triplet energy states that are useful in applications such as organic light emitting devices (OLEDs), as they may give rise to highly efficient devices. Further, the triplet energy of these compounds may be high enough that it may be greater than those of guest dyes used in devices, and thus may serve as host molecules.

The compounds of the present invention are particularly well suited for use in hole transport layers in organic light emitting devices. In one embodiment, the present invention provides an organic light emitting device comprising a hole transport layer which consists essentially of the compounds. In another embodiment, the present invention provides an organic light emitting device comprising the compounds as a constituent of a hole transport layer of an organic light emitting device. Without being bound to any theory, it is believed that protons of the sulfonated polymer in its acidified form may act as p-type dopants, which result in a greater effective work function and may show ability to p-dope the adjacent light-emitting layer, thus resulting in enhanced performance.

In some embodiments, the sulfonated light-emitting polymer may comprise structural units from other monomers, and thus the light-emitting polymer is a copolymer. The copolymer may be random copolymer, or a block copolymer. In one exemplary embodiment, the copolymer further comprises structural units derived from styrene monomer. This may be obtained by appropriately copolymerizing two monomers using suitable initiators, solvent systems, catalysts, reaction conditions, and so on.

In other embodiments, the sulfonated light-emitting polymer may be blended with at least one additional polymer. In one embodiment, the additional polymer is poly(3,4-ethylenedioxythiophene), also known as PEDOT, which is a known light-emitting polymer. In another embodiment, the additional polymer is a polystyrene.

The sulfonated light-emitting polymers of the invention are characterized by molecular weights. The molecular weight of a polymer is determined by any of the techniques known to those skilled in the art, and include viscosity measurements, light scattering, osmometry, and the like. The molecular weight of a polymer is typically represented as a number average molecular weight Mₙ, or weight average molecular weight, M_{w}. A particularly useful technique to determine molecular weight averages is gel permeation chromatography (GPC), from wherein both number average and weight average molecular weights are obtained. In some embodiments, polymers of M_{w} greater than 30,000 grams per mole (g/mol) is desirable, in other embodiments, polymers of M_{w} greater than 50,000 g/mol is desirable, while in yet other embodiments, polymer of M_{w} greater than 80,000 g/mol is desirable.

The sulfonated light emitting polymers are useful in the preparation of opto-electronic devices, for example organic light emitting diodes (OLEDs). Other opto-electronic devices in which the sulfonated light emitting polymers of the present invention may be used include light emitting electrochemical cells, photo detectors, photoconductive cells, photo switches, phototransistors, and phototubes. Thus, in one embodiment, the present invention relates to opto-electronic devices comprising a sulfonated light emitting polymer. In another embodiment, the present invention relates to opto-electronic devices comprising a blend of sulfonated light emitting polymers with another polymer. Suitable polymers for this purpose include emissive polymers, particularly poly(3,4-ethylenedioxythiophene) (PEDOT). The blends typically contain the sulfonated light emitting polymer in amounts ranging from about 20 weight percent (wt %) to about 80 wt %, particularly from about 30 weight percent (wt %) to about 70 wt %, and more particularly, from about 40 weight percent (wt %) to about 600 wt %. In a specific embodiment, the blend is composed of about 50% PEDOT and about 50% sulfonated light emitting polymer.

The sulfonated light-emitting polymer of the present invention are particularly well suited for use in an electroactive layers in organic light emitting devices. In one embodiment, the present invention provides an organic light emitting device comprising an electroactive layer which consists essentially of the sulfonated light-emitting polymer. In another embodiment, the present invention provides an organic light emitting device comprising the sulfonated light-emitting polymer as a constituent of an electroactive layer of an organic light emitting device. In one embodiment, the present invention provides an organic light emitting device comprising the sulfonated light-emitting polymer as a constituent of a light emitting electroactive layer of an organic light emitting device.

An opto-electronic device, exemplified by an organic light emitting device, typically comprises multiple layers which include in the simplest case, an anode layer and a corresponding cathode layer with an organic electroluminescent layer disposed between said anode and said cathode. When a voltage bias is applied across the electrodes, electrons are injected by the cathode into the electroluminescent layer while electrons are removed from (or “holes” are “injected” into) the electroluminescent layer from the anode. Light emission occurs as holes combine with electrons within the electroluminescent layer to form singlet or triplet excitons, light emission occurring as singlet excitons transfer energy to the environment by radiative decay.

Other components which may be present in an organic light emitting device in addition to the anode, cathode and light emitting material include hole injection layers, electron injection layers, and electron transport layers. The electron transport layer need not be in contact with the cathode, and frequently the electron transport layer is not an efficient hole transporter and thus it serves to block holes migrating toward the cathode. During operation of an organic light emitting device comprising an electron transport layer, the majority of charge carriers (i.e. holes and electrons) present in the electron transport layer are electrons and light emission can occur through recombination of holes and electrons present in the electron transport layer. Additional components which may be present in an organic light emitting device include hole transport layers, hole transporting emission (emitting) layers and electron transporting emission (emitting) layers.

The organic electroluminescent layer is a layer within an organic light emitting device which when in operation contains a significant concentration of both electrons and holes and provides sites for exciton formation and light emission. A hole injection layer is a layer in contact with the anode which promotes the injection of holes from the anode into the interior layers of the OLED; and an electron injection layer is a layer in contact with the cathode that promotes the injection of electrons from the cathode into the OLED; an electron transport layer is a layer which facilitates conduction of electrons from cathode to a charge recombination site. The electron transport layer need not be in contact with the cathode, and frequently the electron transport layer is not an efficient hole transporter and thus it serves to block holes migrating toward the cathode. During operation of an organic light emitting device comprising an electron transport layer, the majority of charge carriers (i.e. holes and electrons) present in the electron transport layer are electrons and light emission can occur through recombination of holes and electrons present in the electron transport layer. A hole transport layer is a layer which when the OLED is in operation facilitates conduction of holes from the anode to charge recombination sites and which need not be in contact with the anode. A hole transporting emission layer is a layer in which when the OLED is in operation facilitates the conduction of holes to charge recombination sites, and in which the majority of charge carriers are holes, and in which emission occurs not only through recombination with residual electrons, but also through the transfer of energy from a charge recombination zone elsewhere in the device. An electron transporting emission layer is a layer in which when the OLED is in operation facilitates the conduction of electrons to charge recombination sites, and in which the majority of charge carriers are electrons, and in which emission occurs not only through recombination with residual holes, but also through the transfer of energy from a charge recombination zone elsewhere in the device.

Materials suitable for use as the anode include materials having a bulk conductivity of at least about 100 ohms per square, as measured by a four-point probe technique. Indium tin oxide (ITO) is frequently used as the anode because it is substantially transparent to light transmission and thus facilitates the escape of light emitted from electro-active organic layer. Other materials which may be utilized as the anode layer include tin oxide, indium oxide, zinc oxide, indium zinc oxide, zinc indium tin oxide, antimony oxide, and mixtures thereof.

Materials suitable for use as the cathode include by zero valent metals which can inject negative charge carriers (electrons) into the inner layer(s) of the OLED. Various zero valent metals suitable for use as the cathode include K, Li, Na, Cs, Mg, Ca, Sr, Ba, Al, Ag, Au, In, Sn, Zn, Zr, Sc, Y, elements of the lanthanide series, alloys thereof, and mixtures thereof. Suitable alloy materials for use as the cathode layer include Ag—Mg, Al—Li, In—Mg, Al—Ca, and Al—Au alloys. Layered non-alloy structures may also be employed in the cathode, such as a thin layer of a metal such as calcium, or a metal fluoride, such as LiF, covered by a thicker layer of a zero valent metal, such as aluminum or silver. In particular, the cathode may be composed of a single zero valent metal, and especially of aluminum metal.

Opto-electronic devices according to the present invention include sulfonated and or phosphonated polymers in the hole injection layer. The sulfonated or phosphonated polymers may be used in place of, or in addition to traditional materials such as poly(3,4-ethylenedioxythiophene), which is commercially available from H. C. Stark, Inc. under the BAYTRON® tradename, and polymers based on the thieno[3,4b]thiophene (TT) monomer, commercially available from Air Products Corporation. In particular, the sulfonated or phosphonated polymers may be blended with PEDOT to form a hole injection layer.

Materials suitable for use in hole transporting layers include 1,1-bis((di-4-tolylamino) phenyl)cyclohexane, N,N′-bis(4-methylphenyl)-N,N′-bis(4-ethylphenyl)-(1,1′-(3,3′-dimethyl)biphenyl)-4,4′-diamine, tetrakis-(3-methylphenyl)-N,N,N′,N′-2,5-phenylenediamine, phenyl-4-N,N-diphenylaminostyrene, p-(diethylamino)benzaldehyde diphenylhydrazone, triphenylamine, 1-phenyl-3-(p-(diethylamino)styryl)-5-(p-(diethylamino)phenyl)pyrazoline, 1,2-trans-bis(9H-carbazol-9-yl)cyclobutane, N,N,N′,N′-tetrakis(4-methylphenyl)-(1,1′-biphenyl)-4,4′-diamine, copper phthalocyanine, polyvinylcarbazole, (phenylmethyl)polysilane; poly(3,4-ethylendioxythiophene) (PEDOT), polyaniline, polyvinylcarbazole, triaryldiamine, tetraphenyldiamine, aromatic tertiary amines, hydrazone derivatives, carbazole derivatives, triazole derivatives, imidazole derivatives, oxadiazole derivatives having an amino group, and polythiophenes as disclosed in U.S. Pat. No. 6,023,371.

Materials suitable for use as the electron transport layer include poly(9,9-dioctyl fluorene), tris(8-hydroxyquinolato) aluminum (Alq₃), 2,9-dimethyl-4,7-diphenyl-1,1-phenanthroline, 4,7-diphenyl-1,10-phenanthroline, 2-(4-biphenylyl)-5-(4-t-butylphenyl)-1,3,4-oxadiazole, 3-(4-biphenylyl)-4-phenyl-5-(4-t-butylphenyl)-1,2,4-triazole, 1,3,4-oxadiazole-containing polymers, 1,3,4-triazole-containing polymers, quinoxaline-containing polymers, and cyano-PPV.

Materials suitable for use in the light emitting layer include electroluminescent polymers such as poly(9,9-dioctyl fluorene) and copolymers thereof, such as F8-TFB.

In one aspect, sulfonated light-emitting polymer may form part of the hole collection layer, while in another aspect, sulfonated light-emitting polymer form part of the hole injection layer. Thus, in one aspect, the present invention provides more efficient organic light emitting devices comprising a sulfonated light-emitting polymer.

### Definitions

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthraceneyl groups (n=3) and the like. The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehydes groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆ aromatic radical comprising a nitro group, the nitro group being a functional group. Aromatic radicals include halogenated aromatic radicals such as 4-trifluoromethylphenyl, hexafluoroisopropylidenebis(4-phen-1-yloxy) (i.e., —OPhC(CF₃)₂PhO—), 4-chloromethylphen-1-yl, 3-trifluorovinyl-2-thienyl, 3-trichloromethylphen-1-yl (i.e., 3-CCl₃Ph—), 4-(3-bromoprop-1-yl)phen-1-yl (i.e., 4-BrCH₂CH₂CH₂Ph—), and the like. Further examples of aromatic radicals include 4-allyloxyphen-1-oxy, 4-aminophen-1-yl (i.e., 4-H₂NPh—), 3-aminocarbonylphen-1-yl (i.e., NH₂COPh—), 4-benzoylphen-1-yl, dicyanomethylidenebis(4-phen-1-yloxy) (i.e., —OPhC(CN)₂PhO—), 3-methylphen-1-yl, methylenebis(4-phen-1-yloxy) (i.e., —OPhCH₂PhO—), 2-ethylphen-1-yl, phenylethenyl, 3-formyl-2-thienyl, 2-hexyl-5-furanyl, hexamethylene-1,6-bis(4-phen-1-yloxy) (i.e., —OPh(CH₂)₆PhO—), 4-hydroxymethylphen-1-yl (i.e., 4-HOCH₂Ph—), 4-mercaptomethylphen-1-yl (i.e., 4-HSCH₂Ph—), 4-methylthiophen-1-yl (i.e., 4-CH₃SPh—), 3-methoxyphen-1-yl, 2-methoxycarbonylphen-1-yloxy (e.g. methyl salicyl), 2-nitromethylphen-1-yl (i.e., 2-NO₂CH₂Ph), 3-trimethylsilylphen-1-yl, 4-t-butyldimethylsilylphenl-1-yl, 4-vinylphen-1-yl, vinylidenebis(phenyl), and the like. The term “a C₃-C₁₀ aromatic radical” includes aromatic radicals containing at least three but no more than 10 carbon atoms. The aromatic radical 1-imidazolyl (C₃H₂N₂—) represents a C₃ aromatic radical. The benzyl radical (C₇H₇—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is an cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene-2,2-bis(cyclohex-4-yl) (i.e., —C₆H₁₀C(CF₃)₂ C₆H₁₀—), 2-chloromethylcyclohex-1-yl, 3-difluoromethylenecyclohex-1-yl, 4-trichloromethylcyclohex-1-yloxy, 4-bromodichloromethylcyclohex-1-ylthio, 2-bromoethylcyclopent-1-yl, 2-bromopropylcyclohex-1-yloxy (e.g. CH₃CHBrCH₂C₆H₁₀O—), and the like. Further examples of cycloaliphatic radicals include 4-allyloxycyclohex-1-yl, 4-aminocyclohex-1-yl (i.e., H₂C₆H₁₀—), 4-aminocarbonylcyclopent-1-yl (i.e., NH₂COC₅H₈—), 4-acetyloxycyclohex-1-yl, 2,2-dicyanoisopropylidenebis(cyclohex-4-yloxy) (i.e., —OC₆H₁₀C(CN)₂C₆H₁₀O—), 3-methylcyclohex-1-yl, methylenebis(cyclohex-4-yloxy) (i.e., —OC₆H₁₀CH₂C₆H₁₀O—), 1-ethylcyclobut-1-yl, cyclopropylethenyl, 3-formyl-2-terahydrofuranyl, 2-hexyl-5-tetrahydrofuranyl, hexamethylene-1,6-bis(cyclohex-4-yloxy) (i.e., —OC₆H₁₀(CH₂)₆C₆H₁₀O—), 4-hydroxymethylcyclohex-1-yl (i.e., 4-HOCH₂C₆H₁₀—), 4-mercaptomethylcyclohex-1-yl (i.e., 4-HSCH₂C₆H₁₀—), 4-methylthiocyclohex-1-yl (i.e., 4-CH₃SC₆H₁₀—), 4-methoxycyclohex-1-yl, 2-methoxycarbonylcyclohex-1-yloxy(2-CH₃OCOC₆H₁₀O—), 4-nitromethylcyclohex-1-yl (i.e., NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g. (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

As used herein the term “aliphatic radical” refers to an organic radical having a valence of at least one consisting of a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” organic radicals substituted with a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl, difluorovinylidene, trichloromethyl, bromodichloromethyl, bromoethyl, 2-bromotrimethylene (e.g. —CH₂CHBrCH₂—), and the like. Further examples of aliphatic radicals include allyl, aminocarbonyl (i.e., —CONH₂), carbonyl, 2,2-dicyanoisopropylidene (i.e., —CH₂C(CN)₂CH₂—), methyl (i.e., —CH₃), methylene, ethyl, ethylene, formyl (i.e. —CHO), hexyl, hexamethylene, hydroxymethyl, mercaptomethyl (i.e., —CH₂SH), methylthio (i.e., —SCH₃), methylthiomethyl (i.e., —CH₂SCH₃), methoxy, methoxycarbonyl (i.e., CH₃OCO—), nitromethyl (i.e., —CH₂NO₂), thiocarbonyl, trimethylsilyl (i.e. (CH₃)₃Si—), t-butyldimethylsilyl, 3-trimethyoxysilypropyl (i.e., (CH₃O)₃SiCH₂CH₂CH₂—), vinyl, vinylidene, and the like. By way of further example, a C₁-C₁₀ aliphatic radical contains at least one but no more than 10 carbon atoms. A methyl group (i.e., CH₃—) is an example of a C₁ aliphatic radical. A decyl group (i.e., CH₃(CH2)₉—) is an example of a C₁₀ aliphatic radical.

Any numerical values recited herein include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, preferably from 20 to 80, more preferably from 30 to 70, it is intended that values such as 15 to 85, 22 to 68, 43 to 51, 30 to 32 etc. are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly stated in this application in a similar manner.

### EXAMPLES

Chemicals were purchased from Aldrich Chemical Company, Milwaukee, Wis., and used as received, unless otherwise noted. NMR spectra were recorded on a Bruker Avance 400 (¹H, 400 MHz) spectrometer and referenced versus residual solvent shifts. Flash chromatography was carried out by Fisher Scientific (100-200 mesh) or Aldrich (60-350 mesh) silica gel, prepacked silica gel column by Isco. Thin layer chromatography was carried out on commercially available pre-coated glass plates (Analtech, GF, 250 microns). Gel permeation chromatography (GPC) analysis was performed using a Perkin Elmer instrument using UV-vis detector, and the molecular weights were measured against polystyrene standards. The molecular weights of sulfonated polymers were determined by making a 0.5 mg/mL solution in 0.05M LiBr in DMAc solution, using the same solvent system as eluent. Polyethylene oxides were used as the calibration standards. Polystyrene (PS) used in the triplet measurements was a GPC standard having weight average molecular weight of 18,700 and was obtained from Aldrich Chemical Co., Milwaukee, Wis., USA. A green phosphorescent dye, tris(2-(4-tolyl)phenylpyridine)iridium Ir(mppy)₃ was purchased from American Dye Sources, Canada and used as received. Glass pre-coated with indium tin oxide (ITO) (Applied Films). Poly (3,4-ethylendioxythiophene/polystyrene sulfonate (PEDOT:PSS) was purchased from H.C. Starck Co., GmbH, Leverkusen, Germany. N,N′-diphenyl-N—N″-(bis(3-methylphenyl)-[1,1-biphenyl]-4-4′-diamine (TPD) and 2-(4-biphenyllyl)-5-(4-tert-butylphenyl)-1,3,4-oxadiazole (PBD) was used as a hole injection material and an electron injection material, respectively. Both TPD and PBD were purchased from Aldrich and used as received. All other chemicals and reagents are obtained from Aldrich Chemical Co., Milwaukee, Wis., USA.

X-Ray Photoelectron Spectroscopy (XPS) measurements were performed on a PHI XPS system (model 5500, Physical Electronics, Chanhassen, Minn.) using a monochromatic Al Kα radiation (1486.6 eV) at 200 W. The photoelectrons were analyzed using a hemispherical analyzer operating with a focusing lens at a spot size of 800 μm and at a take-off angle of 45°. Pass energies of 188 and 12 eV were used for survey and high-resolution scans, respectively. To minimize the charging effects on the insulating film, a low energy electron gun was used for charge neutralization. The quantitative compositions of the surface species taken from survey scans were determined from the integrated intensities corrected by atomic sensitivity factors provided by the vendor.

### Synthesis

The sulfonation of poly(N-vinyl carbazole) (PVK) was achieved using two different processes:

### Method 1: Sulfonation Using Sulfuric Acid

PVK (0.194 g) was dissolved in 20 mL of THF and stirred at room temperature. 0.23 g of concentrated sulfuric acid (96.7%) was added dropwise through a syringe. The resulting solution was stirred at room temperature for 24 hours. Then THF solution was concentrated to 5 mL using roto-evaporator and cyclohexane (20 mL) was added to this solution. Solution turned cloudy and polymer was collected by suction filtration and dried under vacuum overnight.

### Method 2: Sulfonation Using a Milder Sulfonating Agent

The method given in Wang et al., Macromolecules, Volume 33, pp. 3232 (2000) was used here. The sulfonating agent, which is a 1.0 Molar (M) acetyl sulfate solution was prepared as follows: 0.76 mL (8.1 mmol) of acetic anhydride (99+%) was dissolved in. 4.0 mL of 1,2-dichloroethane in a 25 mL vial. 0.275 mL (5.0 mmol) of 96.7% sulfuric acid (1.84 g/mL) was added dropwise at 0° C. with stirring. A transparent colorless solution was obtained. The solution was stored in the refrigerator when not being used. A recently ordered PVK (250 mg) was dissolved in THF at room temperature, and the sulfonating agent was added dropwise. The resulting solution was immersed into a water bath and heated to 75° C. and refluxed for 5 h. Then 1.0 mL of ethanol was added to terminate the sulfonation reaction. The solution was cooled overnight. Then, 20 mL of cyclohexane was added to the solution with rapid stirring to precipitate the product sulfonated polymer. The precipitated polymer was isolated by vacuum filtration, washed with ethanol once, and cyclohexane once and dried overnight under vacuum at 80° C. Table 1 provides the results from the synthesis.

| | | | Amount of | | | | |
|---|---|---|---|---|---|---|---|
| | Amount | | sulfonating | Polymer | | | |
| | of PVK¹ | THF | agent | Collected | Degree of | Mn³ | |
| Entry # | (g) | (mL) | (mL) | (g) | Sulfonation² | (g/mol) | PDI³ |
| Ex. 1 | 0.194 | 20 | 0.126 H₂so₄ | 0.23 | 0.58 | | |
| Ex. 2 | 0.25 | 5 | 0.4 | 0.28 | 0.23 | | |
| Ex. 3 | 0.25 | 5 | 0.8 | 0.26 | 0.49 | | |
| Ex. 4 | 0.25 | 5 | 1.2 | 0.23 | 0.51 | | |
| Ex. 5 | 0.25 | 10 | 0.4 | 0.21 | 0.18 | 106,000 | 3.07 |
| Ex. 6 | 0.25 | 10 | 0.8 | 0.24 | 0.53 | 75,500 | 2.03 |
| Ex. 7 | 0.25 | 10 | 1.2 | 0.38 | 0.78 | 48,000 | 1.6 |
| Control³ | | | | | | 64,000 | 3.15 |

¹Starting PVK used in Examples 1–4 were Mw = 1,000,000 polymer from Aldrich, while in examples 5–7 were secondary standard from Aldrich
²Results were calculated by S/C ratio obtained by XPS. 100% DS equals one sulfonate group per repeat unit. Binding energy data suggests all sulfonate groups went to 3 position of the carbazole ring
³Mn and PDI data were obtained by dissolving 7 mg of polymer powder in 1.5 mL of 0.05 M of LiBr in DMAc and used the same as elunt. For comparison purpose, PVK secondary standard were also prepared the same way, Mn and PDI were recorded. A measured Mn of 18,283 (PDI = 2.21) was obtained in CHCl₃ solution with respect to polystyrene standards.

### Example 8

### Kelvin Probe Measurements

Kelvin probe (KP) is a vibrating capacitor technique used to measure change in effective surface work functions of conducting/semi-conducting materials by measuring contact potential differences (CPDs in units of volts, V) relative to a common probe, which correspond to changes in effective surface work functions (in units of electron volts, eV). KP measurements were conducted with a digital Kelvin probe KP6500, purchased from McAllister Technical Services, Coeur d'Alene, Id. 83815, USA.

Samples for the KP measurements were prepared as follows. Indium tin oxide (ITO, about 110 nanometer) coated glass obtained from Applied Films Corporation was used as a conductive substrate. The ITO substrate was cleaned with acetone, iso-proponal and de-ionized water and then baked at 150° C. for 5 mins prior to the KP measurements. A CPD of −0.27 V was obtained for the ITO. Then a layer of sulfonated polymer from Example 7 was spin-coated from its solution in dimethyl sulfoxide (DMSO) atop of the ITO and then baked at 180° C. for 1 minute. A CPD of −0.78 V was measured for the ITO coated with the sulfonated polymer from Example 7 layer. The change in CPD for ITO with and without the sulfonated polymer from Example 7 layer indicates an increase in effective work function of 0.51 eV when the ITO is over-coated with sulfonated polymer from Example 7.

### Example 9

### An OLED Comprising Sulfonated PVK as a Hole-Injection Layer

An Exemplary OLED was made as follows. Glass pre-coated with indium tin oxide (ITO) (Applied Films) was used as the substrate. Then a layer of sulfonated PVK from Example 7 was spin-coated from its solution in DMSO atop the ITO substrate and further baked for 10 mins at 180° C. in ambient environment (with a room temperature of 24C and relative humidity of 32%). Next, a layer (ca. 75 nm) of a green light-emitting polymer (LEP) was then spin-coated atop the layer comprising polymer from Example 7. The device fabrication was finished with the deposition of a bilayer cathode consisting of 4 nm NaF and 110 nm Al via thermal evaporation at a base vacuum of 2*10-6 Torr. Following metal evaporation, the devices were encapsulated using a glass slide sealed with epoxy.

### Comparative Example 1

### A Control OLED

A control OLED was made in the same way as described in Example 9 except for the absence of the sulfonated polymer layer.

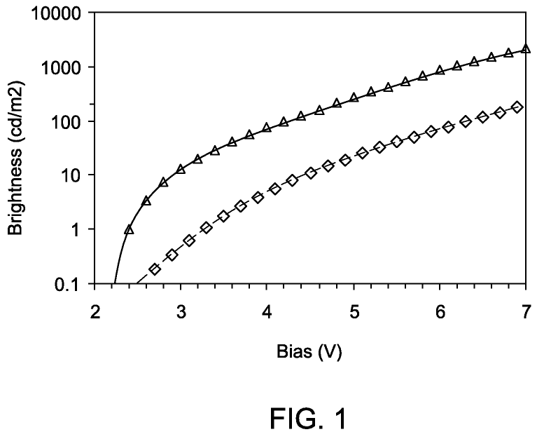

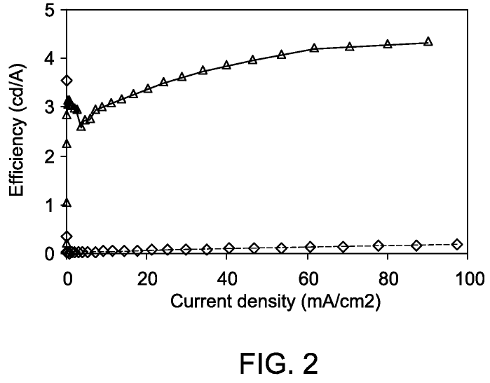

Performance of the Exemplary Device 1 and the Comparative Device 1 was characterized by measuring current-voltage-luminance (I-V-L) characteristics. A photodiode calibrated with a luminance meter (Minolta LS-110) was used to measure the luminance (in units of candela per square meter, cd/m2). FIG. 1 shows a plot of brightness (measured in candela per square meter, cd/m2) as a function of bias voltage (measured in volts, V). FIG. 2 shows the efficiency (measured in candela per ampere, cd/A) as a function of current density (measured in milliamperes per square centimeter, mA/cm2).

It can be seen that introducing the sulfonated polymer as a hole-injection layer significantly improves device performance, as evidenced by the fact that the device from Example 9 comprising the hole-injection layer exhibits much lower driving voltages shown in FIG. 1 and enhanced efficiency shown in FIG. 2, as compared to the device of Comparative Example 1.

### Example 10

### Photo-Responses of Devices

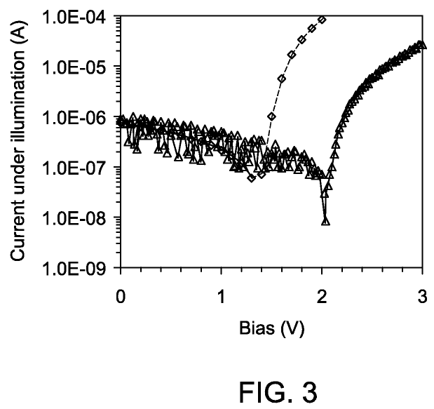

Photo-responses of both the device made as described in Example 9 and Comparative Example 1 were characterized by measuring their current-voltage (IV) characteristics under illumination. A hand-held long wavelength (365 nm) UV-lamp (model: UVL_{—}56, obtained from UVP, Upland, Calif. 91745, U.S.A.) was used as the illumination light source (with an intensity of ca. 3 mW/cm²). The devices were illuminated through the transparent ITO electrode. FIG. 3 shows IV curves of the OLEDs measured under illumination. It can be seen that the device of Example 9 comprising the sulfonated polymer hole-injection layer exhibits a greater open-circuit voltage (Voc, defined as the voltage when current reaches the minimum in the plot) relative to the device of Comparative Example 1.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An opto-electronic device comprising at least one sulfonated light-emitting polymer.

2. An opto-electronic device according to claim 1, wherein the at least one sulfonated light-emitting polymer is selected from sulfonated carbazoles, sulfonated fluorenes, sulfonated polyphenylene, sulfonated polyphenylene vinylenes and combinations thereof.

3. An opto-electronic device according to claim 1, wherein the at least one sulfonated light-emitting polymer comprises structural units of formula I 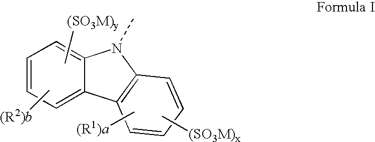
wherein R¹ and R² are independently at each occurrence a C₁-C₄₀ aliphatic radical, a C₃-C₂₀ aromatic radical, a C₃-C₂₀ cycloaliphatic radical;
M is H, a metal cation, a non-metallic inorganic cation, an organic cation or a mixture thereof;
a and b are 0 or integers ranging from 1 to 4;
x is an integer ranging from 1 to 4, y is an integer ranging from 1 to 4, wherein x+a+b+y is less than 8.

4. An opto-electronic device according to claim 1, wherein the at least one sulfonated light-emitting polymer comprises structural units of formula II 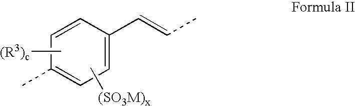
wherein R³ is a C₁-C₄₀ aliphatic radical, a C₃-C₂₀ aromatic radical, a C₃-C₂₀ cycloaliphatic radical;
M is H, a metal cation, a non-metallic inorganic cation, an organic cation or a mixture thereof;
c is 0 or an integer ranging from 1 to 4;
x is an integer ranging from 1 to 4, wherein x+c is less than 4.

5. An opto-electronic device according to claim 1, wherein the at least one sulfonated light-emitting polymer comprises structural units of formula IIIa, or formula IIIb, or formula IIIc or formula IIId 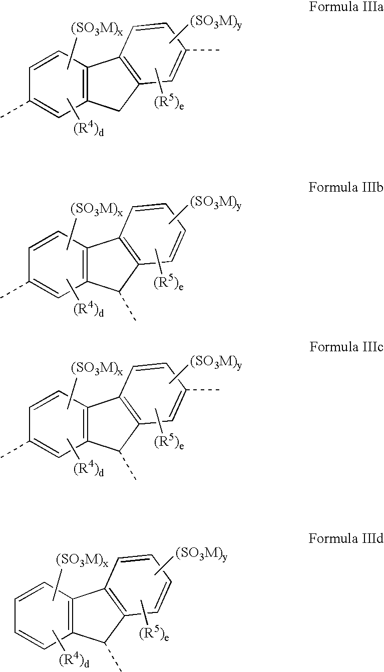
wherein R⁴ and R⁵ are independently at each occurrence a C₁-C₄₀ aliphatic radical, a C₃-C₂₀ aromatic radical, a C₃-C₂₀ cycloaliphatic radical;
M is H, a metal cation, a non-metallic inorganic cation, an organic cation or a mixture thereof;
d and e are 0 or integers ranging from 1 to 4;
x is an integer ranging from 1 to 4, x is an integer ranging from 1 to 4, wherein x+d+e+y is less than 7.

6. An opto-electronic device according to claim 1, wherein the at least one sulfonated light-emitting polymer comprises structural units of formula IV 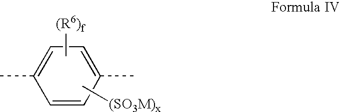
wherein R⁶ is a C₁-C₄₀ aliphatic radical, a C₃-C₂₀ aromatic radical, a C₃-C₂₀ cycloaliphatic radical;
M is H, a metal cation, a non-metallic inorganic cation, an organic cation or a mixture thereof;
f is 0 or an integer ranging from 1 to 4;
x is an integer ranging from 1 to 4, wherein x+f is less than 4.

7. An opto-electronic device according to claim 1, wherein the at least one sulfonated light-emitting polymer further comprises structural units of formula V 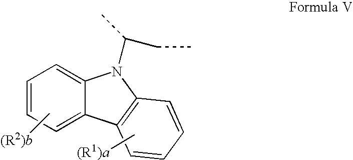
wherein R¹ and R² are independently at each occurrence a C₁-C₄₀ aliphatic radical, a C₃-C₂₀ aromatic radical, a C₃-C₂₀ cycloaliphatic radical;
a and b are 0 or integers ranging from 1 to 4.

8. An opto-electronic device according to claim 1, wherein the at least one sulfonated light-emitting is a block copolymer.

9. An opto-electronic device according to claim 1, wherein the at least one sulfonated light-emitting polymer is a random copolymer.

10. An opto-electronic device according to claim 3, comprising from about 5 mol % to about 95 mol % of the sulfonated light-emitting polymer having structural units of formula I.

11. An opto-electronic device according to claim 3, comprising from about 10 mol % to about 80 mol % of the sulfonated light-emitting polymer having structural units of formula I.

12. An opto-electronic device according to claim 3, comprising from about 20 mol % to about 70 mol % of the sulfonated light-emitting polymer having structural units of formula I.

13. An opto-electronic device according to claim 11, comprising from about 10 mol % to about 80 mol % unsulfonated light-emitting polymer having structural units of formula V.

14. An opto-electronic device according to claim 1, comprising a blend of the at least one sulfonated light-emitting polymer and PEDOT.

15. An opto-electronic device according to claim 1, wherein the at least one sulfonated light-emitting polymer forms a hole injection layer.

16. An opto-electronic device according to claim 1, wherein the at least one sulfonated light-emitting polymer forms a hole collection layer.

17. An opto-electronic device comprising at least one organic electroluminescent layer and a layer comprising at least one sulfonated light-emitting polymer sandwiched between a pair of electrodes.

18. An illumination source comprising at least one opto-electronic device according to claim 17.

19. A display device comprising at least one opto-electronic device according to claim 17.
